(19) United States
(12) Patent Application Publication
(10) Pub. No.: US 2006/0156129 A1
(43) Pub. Date: Jul. 13, 2006

(54) System for maintaining data

(75) Inventors: Nicholas J. Midgley, Five Haydock Mews (GB); Gary P. Noble, Near Broadway (GB)

Correspondence Address: Ojanen Law Offices Ltd., 2665 Riverside Lane NE, Rochester, MN, 55906-3456, US

(73) Assignee: International Business Machines Corporation, Armonk, NY (US)

(21) Appl. No.: 11/280,111

(22) Filed: Nov. 15, 2005

(30) Foreign Application Priority Data
Dec. 15, 2004 (GB) 0427540.0

(51) Int. Cl. G01R 31/28

(52) U.S. Cl. 714/732

(57) ABSTRACT

The invention provides a method for maintaining data stored in a processing device the method comprising the steps of: generating a signature indicative of the data stored in the processing device; communicating the signature to a maintenance node; and receiving updated data from the maintenance node, the updated data being generated by the maintenance node in dependence of the maintenance node comparing the communicated signature with lookup data to determine an update to the data stored in the processing device.

### FIELD OF THE INVENTION

The invention relates to the field of software distribution and in particular, the invention relates to a method and system for maintaining data stored in a data processing device.

### BACKGROUND OF THE INVENTION

Determining if software applications or hardware components installed on computing devices need to be upgraded or replaced has proved a challenge throughout the information technology (IT) industry. For many years, in a standalone environment, it has been necessary for a person to visit each computing device in order to manually determine the hardware configuration of the processing device and the software applications installed along with their version numbers etc. This has proved to be a time consuming task. Improvements to this method of working have therefore been inevitable. In a distributed environment, data stores are populated with a list of approved applications which users of computing devices can inspect in order to determine if there exists a newer version of an application for installing. Alternatively, many corporations communicate to their employees information pertaining to new releases of software and inform the users that they should begin to migrate to the new release.

More sophisticated solutions involve employees installing an application, which allow the scanning of their computing device, in order to detect the processing device's hardware and software configuration. This information is communicated to a central server to determine if there is a new release of a particular software application. If there is a new release of a software application available, a communication is alerted to the employees to upgrade.

But as more, perhaps millions of computing devices work in a disconnected manner, it is becoming difficult to manage and maintain software updates or identify erroneous software and hardware configurations. The computing devices often communicate via wireless means and/or at different frequencies and/or run different hardware and software applications. Therefore, it may not be possible for the central service to communicate updates to the processing device because of the mobility of the processing device; because the central service is not able to locate the devices. Thus, the approaches described above will not work in a disconnected environment, because of the characteristics of the environment itself; which are complex and diverse. Therefore there is a need to solve the above aforementioned problems.

### SUMMARY OF THE INVENTION

The problem of accessing and servicing millions of processing devices may be solved by the present invention that provides a method for maintaining data stored in a processing device, the method comprising the steps of: generating a signature indicative of the data stored in the processing device; and communicating the signature to a maintenance node; receiving updated data from the maintenance node, the updated data being generated by the maintenance node in dependence of the maintenance node comparing the communicated signature with lookup data to determine an update to the data stored on the processing device.

Advantageously, the invention further provides for a processing device to generate a signature indicative of its configuration. The configuration may comprise a combination of the hardware components and the software components installed on the processing device. Preferably, the combination of hardware and software components are the combination of components that are critical to the normal operation of the processing device, for example, an operating system etc. Once the configuration of the processing device is determined, the details pertaining to the configuration are written to a data file. The contents of each entry within the data file are accessed and parsed by a hashing algorithm to create a hash value for each entry within the file. Once each entry has a hash value, a further hash value is generated from the combination of the generated hash values and stored in a signature file. The signature file comprising the generated signature is communicated to a maintenance node for processing. Preferably, the hashing function is an MD5 hashing algorithm. When a hardware component or a software component is updated and/or removed from the processing device, the resulting generated signature also changes. The update may also indicate, via the generated signature, that certain preventative, remedial, or other actions must be performed.

The invention may further be considered a maintenance node that receives the communicated signature from the processing node. The maintenance node performs a lookup in a data store to determine whether an update to the processing device's configuration is available. The maintenance node comprises a number of rules for determining whether a new configuration is available for a particular received signature. The rules enable the processing device to move from one configuration to another in an automated manner. A rule enables the identification of an error condition on the processing node. An error condition may be, for example, a memory failure of the processing device. In response to the detected error condition, a number of corrective actions may be undertaken.

Preferably, a publish/subscribe mechanism or other message based systems are deployed to efficiently process a received signature from a processing node.

The invention further provides a system for maintaining data stored in a processing device, the system comprising: a generator component for generating a signature indicative of the data stored on the processing device; the generator component communicating the signature to a maintenance processing node; and a receiver component for receiving updated data from the maintenance node, the updated data being generated by the maintenance node in dependence of the maintenance node comparing the communicated signature with lookup data to determine an update to the data stored on the processing device.

Yet, the invention also provides a system and a contract service for identifying data updated to a processing device, the system comprising: a receiver component for receiving a signature from a processing node, the received signature being indicative of the data stored on the processing device; a comparator component, for comparing the received signature with lookup data to determine an update to the data stored on the processing device.

The invention may further be considered a computer program product loadable into the internal memory of a digital computer, comprising software code portions for performing, when said product is run on a computer, to carry out the invention as claimed above.

### BRIEF DESCRIPTION OF THE DRAWING

Embodiments of the invention are described below in detail, by way of example only, with reference to the accompanying Drawing.

FIG. 1 is a simplified block diagram of a software distribution system of an embodiment of the present invention.

FIG. 2 is a simplified block diagram of further detail of a generator component of FIG. 1 in which it generates a signature indicative of the configuration of the processing device in accordance with features of the invention.

FIG. 3 is a block diagram of a comparator component of FIG. 1 that processes the signature and may recommend a number of actions in response to the processed signature in accordance with an embodiment of the invention.

FIG. 4 illustrates a flow chart depicting the operational steps to create signature characteristic of the configuration of a processing device in accordance with features of the invention.

FIG. 5 is a flow chart of the operational steps of the maintenance node in accordance with an embodiment of the invention.

FIG. 6 is a flow chart of the operational steps of the maintenance node in accordance with an embodiment of the invention.

### DETAILED DESCRIPTION OF THE INVENTION

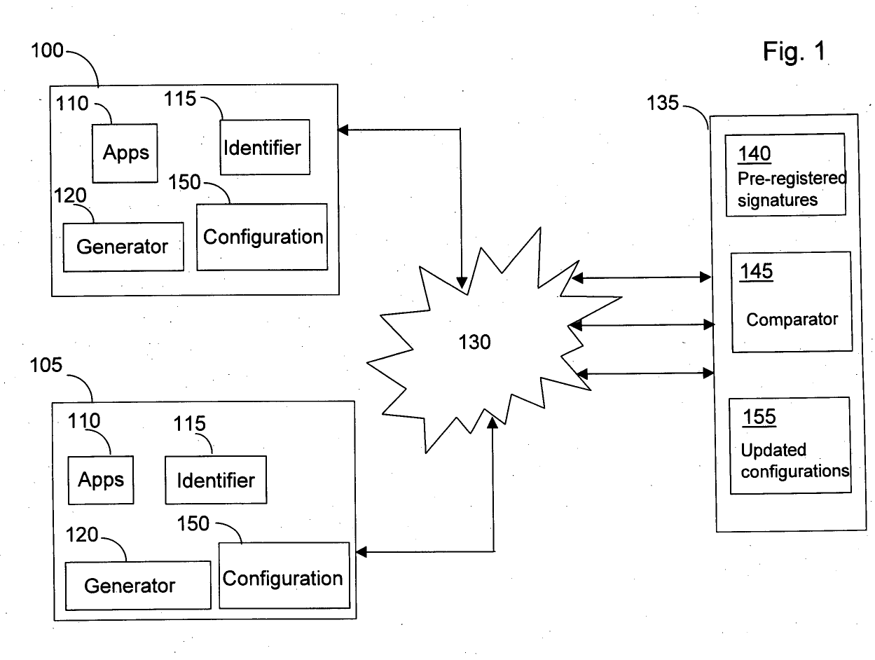

FIG. 1 illustrates the components of the software distribution system of the present invention in a simplified block diagram. The software distribution system comprises a number of processing devices 100, 105. Each processing device 100, 105 is adapted for generating a signature of its current configuration for communicating to a maintenance node 135. The processing device 100, 105 may comprise any data processing device 100, 105 which is adapted for communication with a network 130, for example, a mobile phone, a personal digital assistant, a laptop computer, a television digital set top box, or other household or industrial appliances wherein the use of an embedded computer devices are deployed. The network 130 may comprise any form of network 130, for example, the Internet, an Intranet, a local area network, a wide area network or a wireless network. The network 130 may be a secure network, or an insecure network.

As is known in the art, a processing device 100, 105 comprises a number of applications 110. These applications may comprise an operating system, low level hard-coded applications which the processing device 100, 105 requires on start-up, critical task performing applications, word processing applications, etc. Certain applications may be specific to certain processing devices, for example, a mobile phone manufacturer A may run a different operating system on their mobile phones than mobile phone manufacturer B. Some processing devices 100, 105 may be sold with a set of applications 110 defined by an identifier of the version number of the set installed on the processing device 100, 105.

In accordance with the present invention, each processing device 100, 105 further comprises a configuration component 150 for storing a list of the names of each of the installed applications and other details such as, the application's version number and installation date. The configuration component 150 also stores details of the processing device's 100, 105 hardware configuration, such as, the type and the number of disk drives, the amount of random access memory (RAM) and the type of communication devices etc.

The processing device 100, 105 further comprises an identifying component 115 for identifying an application or a hardware update being performed by the processing device 100, 105. When a new application, an update to an exiting application, or a new piece of hardware is installed on the processing device 100, 105, details of the update are registered in a data store. The details may comprise the name of the application or hardware device, the version number and the installation date. Further, if an application or piece of hardware is removed from the processing device 100, 105 this information is also recorded in the data store. The identification component 115, may periodically check the processing device for an update, for example, on start-up of the processing device 100, 115 through a boot sequence.

On identification of a new entry in the data store, the identifying component 115 parses the new entry and extracts the details pertaining to the update, new installation or removal of an application or hardware device. The extracted information is communicated to the configuration component 150 for updating in the configuration component's 150 list of applications and hardware devices. In response to an update, the configuration component 150 generates a configuration file comprising a list of file names of identified core software applications and the file name of a file comprising a list of hardware devices. The core software applications may comprise any one or a combination of software applications that are determined to be critical to the running of the processing device 100, 105.

The processing device 100, 105 further comprises a generator component 120 for generating a signature indicative of the processing device's 100, 105 current configuration. The generator component 120 requests the configuration file from the configuration component 150. On receipt of the configuration file, the generation component 120 accesses each of the files listed within the configuration file in order to parse the contents of the each of the files to generate a hash value for each of the listed files. When generating a hash value for each of the files, preferably, the hash value is created by an MD5 hashing algorithm, although it will be appreciated by a person skilled in the art, that other types of hashing algorithms may be used.

On generation of each of the hash values, the generation component 120 also creates a hash file and then writes to the file, each of the file names and their corresponding hash values. On completion of the hash file, the generation component 120 parses the content of the hash file and generates a further hash value, which is written to a signature file for transmitting to the maintenance node 135.

The software distribution system further comprises a maintenance node 135 for processing the received signature from the processing device 100, 105. The maintenance node 135 may comprise any server technology adapted for processing a received signature from a processing device 100, 105 and communicating an instruction in response to the processed signature, to the processing device 100, 105. In order to process a received signature, the maintenance node 135 comprises a pre-registered signature component 140, a comparator component 145 and an updated configuration component 155. Each of these components co-operate with each other in order to determine if a software update or hardware update is available in response to the received signature.

The pre-registered signature component 140 of the maintenance node 135 manages and maintains a data store of pre-registered signatures for each processing device 100, 105 registered with the software distribution system. The data store comprises a list of information pertaining to each processing node, for example, an identifier of the processing device 100, 105, a registered configuration for the processing device 100, 105 and a target configuration for the processing device 100, 105, if available. Other information may comprise the current signature of the processing device 100, 105 and the date and time of when a signature was last received from the processing device 100, 105. The pre-registered signature component 140 periodically updates the data store to ensure that the information pertaining to each processing device 100, 105 is complete and accurate. The frequency at which this is performed is dependent on the volume of activity within the software distribution system. As a general guide, the data store may be updated on the determination of a new processing device 100, 105 registering with the maintenance node 135, a new target configuration being available, or a new signature being received for an already registered processing device 100, 105.

An update configuration component 155 of the maintenance node 135 manages and maintains a data store of target configurations for a registered signature from a processing device 100, 105. The data store comprises a list of signatures, pertaining to each of the processing devices' 100, 105 registered configuration, along with a signature pertaining to a target configuration for each processing device 100, 105 (if a target configuration is available) and any preconditions before an available software update may be communicated to the processing device 100, 105. A precondition may state that a particular version of an application must already be installed on the processing device 100, 105 before an update can take place, or that the update can only take place between certain hours of the day, for example. A precondition may be indicative of a precondition of the processing device 100, 105 or of the hardware or software update to be performed. Other data may comprise comments pertaining to the registered configuration, the number of processing device 100, 105 registered as having a particular signature or the number updates communicated to the processing node, the cost of instructing a plurality of processing devices 100, 105 to update their configuration to a newer version over a particular network at a particular time etc.

A comparator component 145 of the maintenance node 135 determines by following a number of rules, on receipt of a signature from a processing device 100, 105, whether the current configuration of the processing device 100, 105 is as expected and if so whether there is or is not a new target configuration available etc. The comparator component 145 logs the outcome of the rules and communicates the updates to the pre-registered signature component 140 and the update configuration component 155 for updating in their respective data stores.

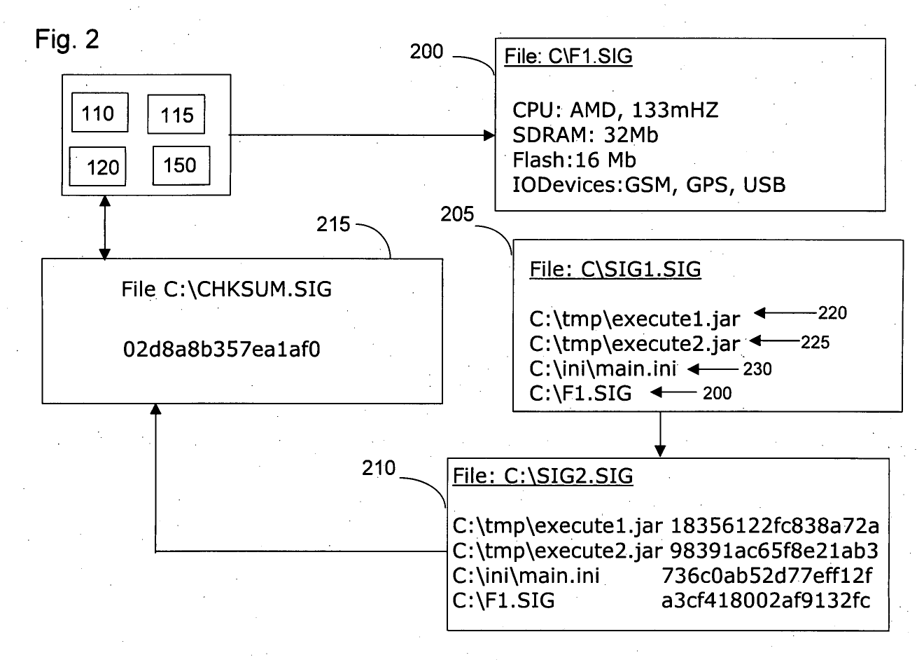

Moving onto FIG. 2, the components of the processing device 100, 105 and their outputs are explained in greater detail. As previously explained each processing device 100, 105 comprises installed applications and hardware components that depict a configuration for the processing device 100, 105. Taking an embedded device, as an example, its configuration may comprise an operating system for embedded devices version 1.3, a communications component version 2.4 and a data processing component version 3.1. As previously explained, in order to determine the configuration of a processing device 100, 105, an identifying component 115 and a configuration component 150 monitor the processing device 100, 105 for activity of the addition, the update and/or the removal of hardware and software applications. A generator component 120 receives data from the configuration component 150 and generates a signature for transmitting to the maintenance node 135. For example and with reference to FIG. 2, it is shown how the generation component 120 operates in more detail.

As shown in FIG. 2, a file called SIG1.SIG 205 is stored in the configuration data store and comprises a list of file names, namely, execute1.jar 220, execute2.jar 225, main.ini 230 and F1.SIG 200. By way of example only, one such file—F1.SIG 200 may comprises details pertaining to the processing device's 100, 105 hardware configuration, namely an AMD 133 megahertz (MHz) central processing unit (CPU), 32 megabytes (Mb) of random access memory (RAM), 16 Mb of flash memory and global system for mobile communication (GSM), global positioning system (GPS) and universal serial bus (USB) input/output devices. In order to generate a signature for F1.SIG 200, the generator component 120 parses each character of the contents of the F1.SIG 200 file and generates a hash value. For example, parsing the contents of the F1.SIG file 200: CPU: AMD 133 MHz; SDRAM: 32 Mb; Flash: 16 Mb; IODevices: GSM GPS USB. Then an MD5 128 bit hashing algorithm on the content of F1.SIG 200 generates the following hash value: a3cf418002af9132fc. The above step is carried out for each file listed within the configuration file 205, until each file is associated with a hashing value representative of its contents. As shown in FIG. 2, block 210, the file execute1.jar 220 has a hash value of 18356122fc838a72a; the file execute2.jar 225 has a hash value of 98391ac65f8e21ab3; the file main.ini 230 has a hash value of 736c0ab52d77eff12f; and the file F1.SIG 200 has a hash value of a3cf418002af9132fc.

Thus, the generation component 120 generates a hash value representative of the contents of each file in the configuration file 205, it creates a hash file SIG2.SIG (210) and writes to the file, the file names of each of the files listed in the configuration file 205 and its corresponding generated hash value. Once the creation and all the relevant data has been written to the hash file 210, the generation component 120 proceeds to parse the contents of the hash file 210 and creates a signature file (CHKSUM.SIG 215) and generates a further hash value (215) representative of the contents of the hash file 210 and writes the hash value to the signature file 215. The signature file 215 comprising the signature is communicated to a maintenance node 135 for processing.

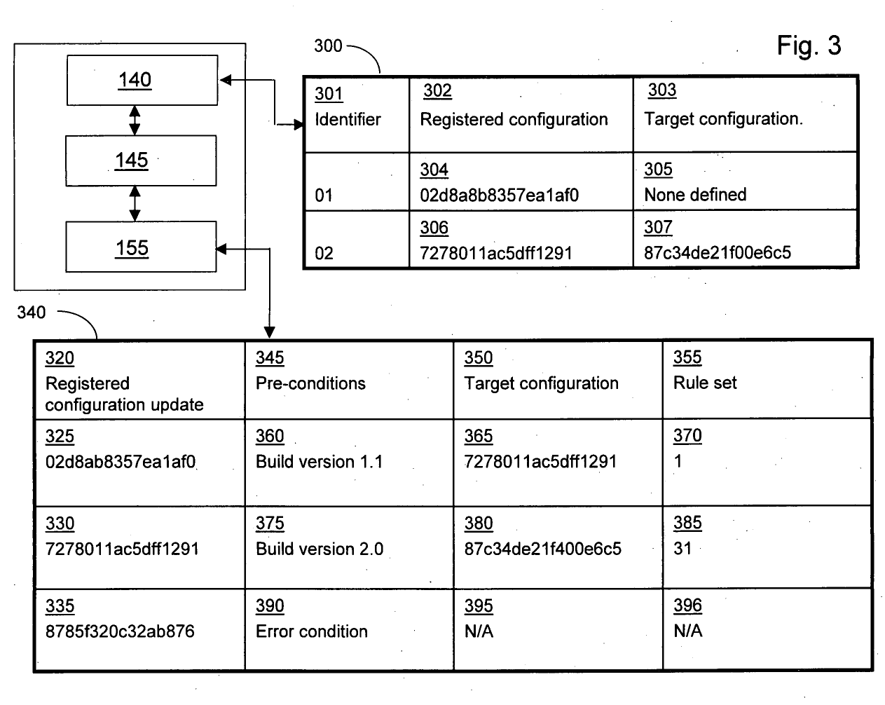

Moving onto FIG. 3, as previously explained, the maintenance node 135 comprises a pre-registered signatures component 140, a comparator component 145 and an update configuration component 155. The pre-registered component 140 manages and maintains a data store 300 comprising data pertaining to each registered processing device 100, an identifier 301 indicative of the processing device 100, 105, its previously registered configuration signature 302 and a target configuration signature 303 (if available). For example, a processing device 100 comprises an identifier 301 of 01, having a registered configuration 302 of 02d8a8b8357ea1af0 (304) and a target configuration 303 of no target configuration 305 defined. Another processing device 105 has an identifier 301 of 02 having a registered configuration 302 of 7278011ac5dff1291 (306) and a target configuration 303 of 87c34de21f00e6c5 (307).

The current signature of the device and the date and time the current configuration may be updated by the pre-registered signature component 140 when it receives inputs from the comparator component 145, the update configuration component 155, and a signature from a processing node 100, 105. The update configuration component 155 manages and maintains a data store 340 comprising information pertaining to each registered signature. For example, the data store 340 provides data entries for the registered configuration update signature 320, any preconditions 345, a target configuration 350 and a rule set 355. For example, taking each row within the data store 340, the registered configuration update 320 for the signature 02d8ab8357ea1af0 comprises entries pertaining to the build version 360, a target configuration 365 and the rule set 370 to be deployed on identification of the signature 02d8ab8357ea1af0. The next registered configuration update for the signature 7278011ac5dff1291 (330) comprises a corresponding entry for a precondition 345, i.e. build version 2.0 375, must be installed in the processing device 100, 105, a target configuration 350 of 87c34de21f400e6c5 (380) and a rule set 355, of 31, 385. The last registered configuration update 340 for the signature 8785f320c32ab876 (335), comprises an entry for a precondition 345 an entry for a target configuration 350 (not applicable 395) and a rule set 355 (not applicable 395). In this instance the signature 8785f320c32ab876 (335) is indicative of an error condition 390 being exhibited by the processing device 100, 105 and diagnostic procedure may be undertaken by the maintenance node in order to rectify the error. The diagnostic process may involve the identification and transmission of a software patch which resolves the error condition.

The comparator component 145 comprises a rules engine for receiving a signature from a processing device 100, 105, and using the data from the update configuration data store for determining whether a configuration update is available for the processing device 100, 105. On determining whether an update is available, the data is communicated to the pre-registered component 140 for storing in the data store 301.

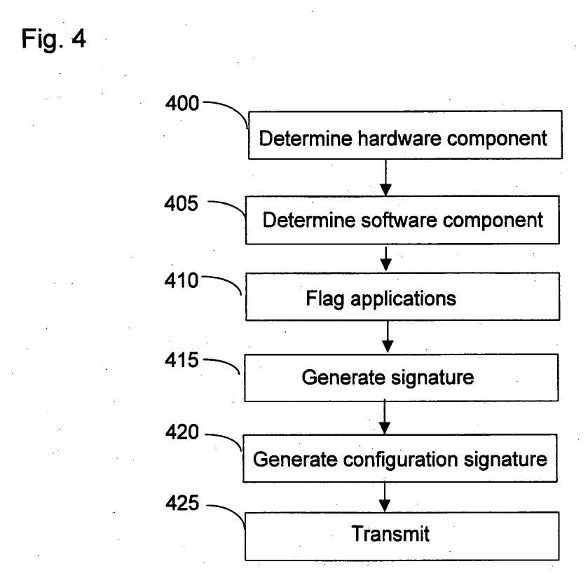

In use and with reference to FIG. 4, the processing device 100, 105 determines the hardware configuration of the processing device 100, 105 and records details of the hardware components in a file, at step 400 and at step 405 determines the software applications 110 installed on the processing device 100, 105. The core software applications of the processing device 100, 105, for example, the operating system, any initialization files and/or image files etc are recorded in a configuration file 205, along with the name of the file detailing the hardware components of the processing device, at step 410. For each file listed in the configuration file 205, a signature is generated and recorded in a hash file 210 at step 415. Once each file has a generated signature, a further signature is generated by creating a further hash value from the combination of the individual signatures and storing in a signature file, at step 420. The signature is transmitted to the maintenance node 135 for processing at step 425.

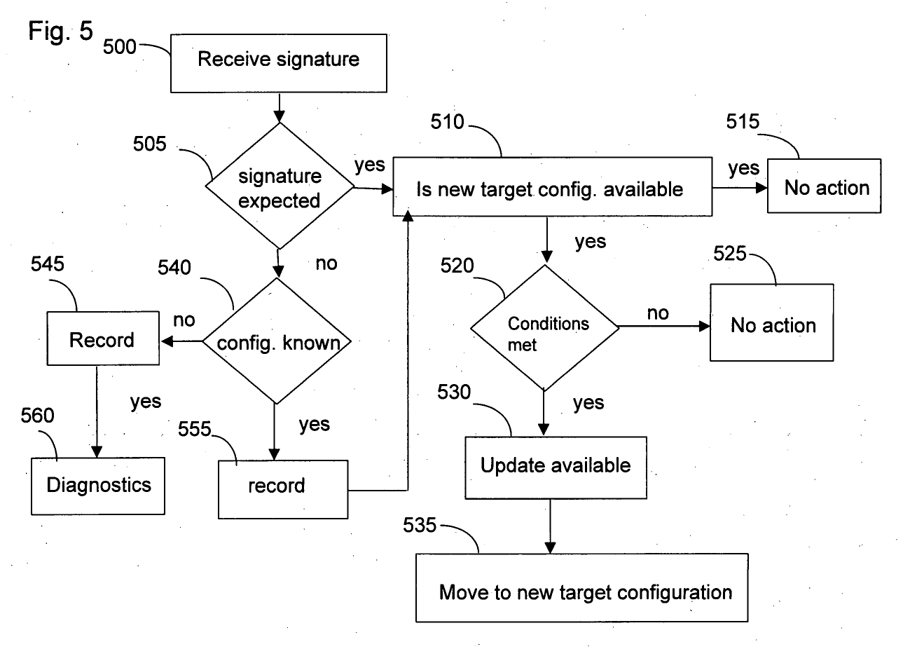

In use and with reference to FIG. 5, the maintenance node 135 receives a signature from a processing device 100, 105 at step 500. A determination is performed at step 505 to establish whether the signature is the expected signature from the processing device 100, 105. If the determination is positive, control moves to step 510 and a further determination is made to identify whether there is a new target configuration available for the processing device 100, 105 by performing a lookup in the updated configuration data store 155. If, the determination is negative, i.e. there is no new configuration available, control move to step 515 and no further action is performed by the maintenance node 135 on this occasion.

Moving back to step 510, if there is a new target configuration available, control moves to step 520 and a determination is made to determine whether any pre-conditions (345) must be met before the maintenance node 135 can communicate the new target configuration to the processing device 100, 105. For example, communication may only be initiated with the processing device 100, 105 after 18:00 hours on a Tuesday, but before 8:00 am on the following Wednesday, or a particular version of a configuration must be installed before installing a new version. If the specified pre-conditions have not been met, control moves to step 525 and no further action is taken by the maintenance node 135 on this occasion. Alternatively, if the conditions have been met and a new configuration (350) is available at step 530, the maintenance node 135 instructs the processing device 100, 105 to move to the new target configuration at step 535. The instruction may comprise sending the target configuration to the processing device 100, 105 or alternatively, sending the processing device 100, 105 details of how to access the target configuration for installation at a particular location.

Moving back to step 505, if the signature is not the expected signature of the processing device 100, 105, control moves to step 540 and a determination is made to identify whether the configuration depicted by the signature is a known configuration. If the determination is positive, control moves to step 545 and the signature is recorded in a data store by the pre-registered signature component 140. Once recorded, control moves to step 510 for determining whether there is a target configuration (303) available for the signature.

Moving back to step 540, if the configuration depicted by the signature is not a known configuration, the configuration is recorded in a data store (320) at step 545. Because the configuration is determined as a new configuration, this may indicate that the processing node is exhibiting operational error characteristics (390) and a number of diagnostic tools may be initiated by the maintenance node in order to identify the error condition at step 560.

In an alternative embodiment, a publish/subscribe mechanism may be employed in order to process a received signature. The comparator component 155 is modified to operate as a broker component for publishing signatures from processing devices 100, 105. As signatures are received, the signatures are compared to the published signatures and each received signature that is mapped to a published signature is placed in a queue corresponding to the published signature for processing.

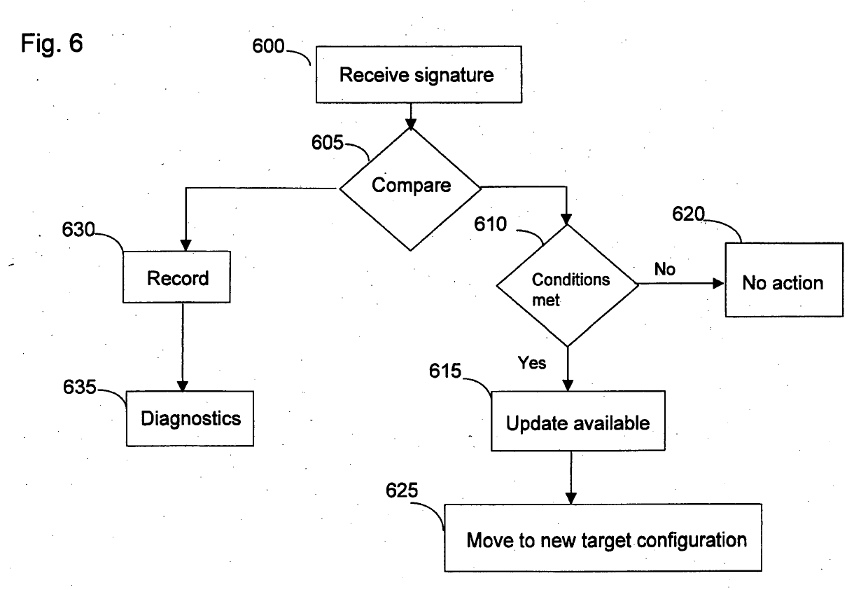

With reference to FIG. 6, at step 600, the comparator component 155, receives a signature from a processing device 100, 105. As each of the signatures is received at step 600, the signature is compared against a list of published known signatures, at step 605. If a match is found for the signature, it is determined that the signature is a known and a valid signature—control moves to step 610 and a determination is made as to whether the conditions for an configuration update have been met, if the determination is negative, control moves to step 620 and no further action is performed on this occasion. Alternatively, if the determination is positive, control moves to step 615 and a determination is made to identify if a configuration update is available for the processing device. If an update is available the maintenance node instructs the processing node to move to its next configuration at step 625. Moving back to control 605, if the signature is not a known signature, control moves to step 630 and the signature is recorded in the configuration data store 301 and if necessary diagnostic actions may be undertaken at step 635.

While various embodiments of the present invention have been described above, it should be understood that they have been presented by way of example and not limitation and that variations are possible. Thus, the breadth and scope of the present invention should not be limited by any of the above-described exemplary embodiments, but should be defined only in accordance with the following claims and their equivalents.

What is claimed is:

1. A method for maintaining data stored in a data processing device, the method comprising the steps of:
(a) generating a signature indicative of the data stored in the data processing device;
(b) communicating the signature to a maintenance node; and
(c) receiving updated data from the maintenance node depending upon the maintenance node determining if the signature is expected from the data processing device.

2. A method as claimed in claim 1, wherein the signature is generated by a hash function.

3. A method as claimed in claim 2, wherein the hash function is an MD5 hashing algorithm.

4. A method as claimed in claim 1, wherein the data is indicative of a configuration of the data processing device.

5. A method as claimed in claim 4, wherein the configuration of the data processing device is determined by identifying the hardware and software components installed on the data processing device.

6. A method as claimed in claim 5, wherein a hash value for each identified hardware and software component is generated and a further hash value is generated from each of the generated hash values for communicating to the maintenance node.

7. A method as claimed in claim 1, wherein the received signature is processing by a publish/subscribe mechanism.

8. A method for identifying a data update for communicating to a processing device, the method comprising the steps of:
(a) receiving a signature from the processing node, the received signature being indicative of data stored on the processing device;
(b) comparing the received signature with lookup data to determine an update to the data stored on the processing device.

9. A method as claimed in claim 8, wherein the update is communicated to the processing device.

10. A system for maintaining data stored in a processing device, the system comprising:
(a) a generator component for generating a signature indicative of the data stored in the processing device;
(b) the generator component communicating the signature to a maintenance processing node; and
(c) a receiver for receiving updated data from the maintenance node, the updated data being generated by the maintenance node in dependence of the maintenance node comparing the communicated signature with lookup data to determine an update to the data stored on the processing device.

11. A system as claimed in claim 10, wherein the signature is generated by a hash function.

12. A system as claimed in claim 11, wherein the hash function is an MD5 hashing algorithm.

13. A system as claimed in claim 10, wherein the data is indicative of a configuration of the data processing device.

14. A system as claimed in claim 13 further comprises an identifier component for identifying the configuration of the data processing device by determining the hardware components and the software components installed on the data processing device.

15. A system as claimed in claim 14, wherein the generator component generates a hash value for each identified hardware component and software component and generates a further hash value from the combination of each of the generated hash values for communicating to the maintenance node.

16. A system as claimed in claim 10, wherein a receiver component processed the received signature by a publish/subscribe mechanism.

17. A system for identifying a data update for communication to a processing device, the system comprising:
(a) a receiver component for receiving a signature from the processing node, the received signature being indicative of data stored on the processing device; and
(b) a comparator component for comparing the received signature with lookup data to determine an update to the data stored in the processing device.

18. A system as claimed in claim 17, further comprises a communicator component for communicating the update to the processing device.

19. A computer program product comprising a computer usable medium having computer usable program code, wherein when the computer usable program code is loadable into the internal memory of a processing device, causes the processing device to:
(a) generate a signature indicative of the data stored in the data processing device;
(b) communicate the signature to a maintenance node across a network;
(c) receive updated data from the maintenance node if the maintenance node determines the signature is expected from the data processing device.

20. The computer program product of 19, wherein the program code causes the data processing device to generate the signature using a hash function.

21. The computer program product of claim 20, wherein the program code causes the data processing device to generate the signature indicative of a configuration of the data processing by identifying the hardware and software components installed on the data processing device.

22. The computer program product of claim 21, wherein a hash value for each identified hardware and software component is generated, and a further hash value is generated from each of the generated hash values.

23. The computer program product of claim 22, wherein the received signature is processing by a publish/subscribe mechanism.

24. A service contract for managing service transactions between at least one microprocessor device and a maintenance mode coupled to a communication network, the at least one microprocessor device having processing hardware and/or software, the service contract comprising:
(a) a plurality of hash values generated by the service contract, one of the plurality of hash values pertaining to each of the hardware and/or software configuration of the at least one microprocessor device;
(b) a configuration hash value generated by the service contract, the configuration hash value generated from the combination of the plurality of hash values pertaining to each of the at least one microprocessor devices;
(c) a signature file unique to each of the at least one microprocessor devices, the signature file generated by the service contract indicative of the configuration hash value of the at least one microprocessor device.

25. The service contract of claim 24, further comprising:
(a) a maintenance node coupled to the at least one processing device, the maintenance node receiving a signature for each of the plurality of processing devices; the maintenance node comprising:
(i) a pre-registered signature component having expected signatures of each of the plurality of processing devices;
(ii) a comparator component having a rules engine that compares the received signature with the expected signature;
(iii) an update configuration component that transmits updated data to one of the plurality of processing devices when the received signature matches the expected signature and when updated data for the processing device are available.

26. The service contract of claim 25, further comprising a target configuration stored in the maintenance node, the target configuration indicative of the updated data to be transmitted to one of the plurality of processing devices.
